(19) United States
(12) Patent Application Publication
(10) Pub. No.: US 2021/0327891 A1
(43) Pub. Date: Oct. 21, 2021

(54) STACK FOR 3D-NAND MEMORY CELL

(71) Applicant: Applied Materials, Inc., Santa Clara, CA (US)

(72) Inventors: Takehito Koshizawa, San Jose, CA (US); Bo Qi, San Jose, CA (US); Abhijit Basu Mallick, Palo Alto, CA (US); Huiyuan Wang, Santa Clara, CA (US); Susmit Singha Roy, Sunnyvale, CA (US)

(73) Assignee: Applied Materials, Inc., Santa Clara, CA (US)

(21) Appl. No.: 17/223,351

(22) Filed: Apr. 6, 2021

Related U.S. Application Data
(60) Provisional application No. 63/010,851, filed on Apr. 16, 2020.

(51) Int. Cl. H01L 27/11556; H01L 21/8234; H01L 27/11582

(52) U.S. Cl. CPC H01L 27/11556; H01L 27/11582; H01L 21/823412; H01L 21/823437

(57) ABSTRACT

Memory devices and methods of manufacturing memory devices are provided. A plasma enhanced chemical vapor deposition (PECVD) method to form a memory cell film stack having more than 50 layers as an alternative for 3D-NAND cells is described. The memory stack comprises alternating layers of a first material layer and a second material layer.

### CROSS-REFERENCE TO RELATED APPLICATIONS

This application claims priority to U.S. Provisional Application No. 63/010,851, filed Apr. 16, 2020, the entire disclosure of which is hereby incorporated by reference herein.

### TECHNICAL FIELD

Embodiments of the present disclosure pertain to the field of electronic devices and methods and apparatus for manufacturing electronic devices. More particularly, embodiments of the disclosure provide 3D-NAND memory cells and methods for forming 3D-NAND memory cells.

### BACKGROUND

Semiconductor technology has advanced at a rapid pace and device dimensions have shrunk with advancing technology to provide faster processing and storage per unit space. In NAND devices, one of the main goals is to increase storage per unit space, which results in an increase of the vertical dimensions or the stack height of the 3D NAND devices.

Existing 3D-NAND memory stacks with alternating layers of oxide and nitride require replacement metal gate (RMG) process to build word lines. Realization of increased vertical stack height in 3D NAND devices can be problematic. A drawback of current processes using alternating layers of oxide and nitride in the memory stack is that the memory hole etching process is challenging, resulting in tapering, bending, and bowing of the memory hole.

Accordingly, there is a need in the art for 3D-NAND devices and methods for forming the 3D-NAND devices with improved film stack etch process margins.

### SUMMARY

One or more embodiments of the disclosure are directed to method of forming devices. In one embodiment, a method of forming a device comprises: treating a surface of a substrate with a plasma, the plasma comprising one or more of ammonia (NH₃), nitrogen (N₂) or hydrogen (H₂); forming a wetting layer on the substrate; transitioning from a low deposition rate to a high deposition rate; and exposing the substrate to at least one precursor to deposit a stack of alternating layers of a first material layer and a second material layer to form a memory stack.

Additional embodiments of the disclosure are directed to semiconductor memory devices. In one an embodiment, a semiconductor memory device comprises: a memory stack comprising alternating first material layers and second material layers in a first portion of the device; a memory stack in a second portion of the device, the memory stack comprising alternating dielectric layers and word lines, a plurality of bit lines extending through the memory stack, and word line isolations extending from a top surface of the word lines.

Further embodiments of the disclosure are directed to a method of forming a memory device. In one embodiment, a method of forming a memory device comprises: forming a memory channel through a memory stack, the memory stack comprising alternating layers of a first material layer and a second material layer; removing one or more first material layers from the memory stack to form a first opening; forming a word line replacement material in the first opening; removing one or more second material layers from the memory stack form a second opening; forming a dielectric layer in the second opening, the dielectric layer having an air gap; and forming word line isolations.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 depicts a flow process diagram of an embodiment of a method of forming a memory device according to embodiments described herein;

FIG. 2 illustrates a cross-sectional view of a device with a memory stack according to one or more embodiments;

FIG. 3 illustrates a cross-sectional view of a substrate according to one or more embodiments;

FIG. 4A illustrates a cross-sectional view of a substrate after formation of an opening according to one or more embodiments;

FIG. 4B illustrates a cross-sectional view region 103 of the substrate of FIG. 4A according to one of more embodiments;

FIG. 5A illustrates a cross-sectional view of a substrate according to one or more embodiments;

FIG. 5B illustrates an expanded view of region 103 according to one or more embodiments;

FIG. 6A illustrates a cross-sectional view of a substrate according to one or more embodiments;

FIG. 6B illustrates an expanded view of region 103 after according to one or more embodiments;

FIG. 7A illustrates a cross-sectional view of a substrate according to one or more embodiments;

FIG. 7B illustrates an expanded view of region 103 after according to one or more embodiments;

FIG. 8A illustrates a cross-sectional view of a substrate according to one or more embodiments;

FIG. 8B illustrates an expanded view of region 103 after according to one or more embodiments;

FIG. 9 illustrates a cross-sectional view of a substrate after slit patterning according to one or more embodiments;

FIG. 10 illustrates a cross-sectional view of a substrate after a sacrificial layer is removed according to one or more embodiments;

FIG. 11A illustrates a cross-sectional view of a substrate according to one or more embodiments;

FIG. 11B illustrates an expanded view of region 200 of FIG. 11A;

FIG. 12A illustrates a cross-sectional view of a substrate according to one or more embodiments;

FIG. 12B illustrates an expanded view of region 200 of FIG. 12A;

FIG. 13A illustrates a cross-sectional view of a substrate according to one or more embodiments;

FIG. 13B illustrates an expanded view of region 200 of FIG. 13A;

FIG. 14A illustrates a cross-sectional view of a substrate according to one or more embodiments;

FIG. 14B illustrates an expanded view of region 200 of FIG. 14A;

FIG. 15 illustrates a cross-sectional view of a substrate according to one or more embodiments; and

FIG. 16 illustrates a cross-sectional view of a substrate according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

Existing 3D-NAND memory stacks with alternating layers of oxide and nitride require replacement metal gate (RMG) process to build word lines. Because the stack height is becoming larger, high aspect ratio (HAR) memory hole etch/fill processes and stress control are becoming more difficult.

One or more embodiments advantageously provide a PECVD deposition method to form a memory cell film stack having more than 50 layers as an alternative for 3D-NAND cells.

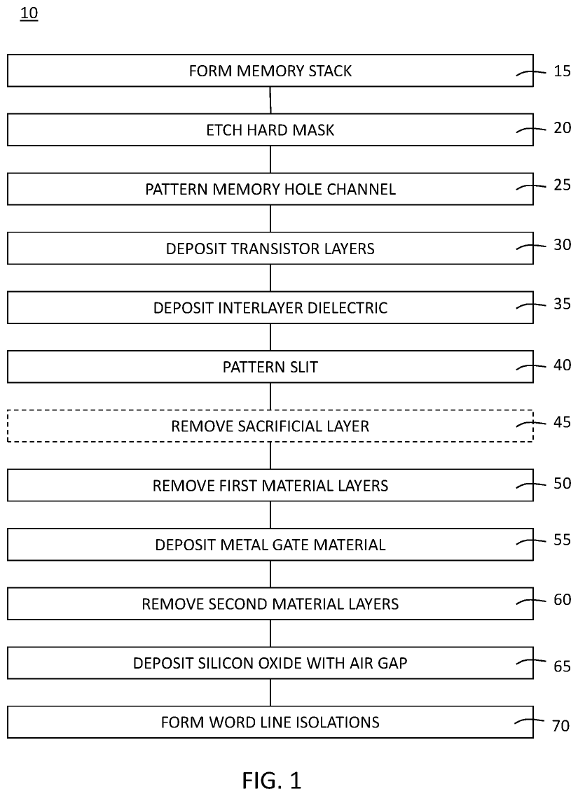

FIG. 1 illustrates a process flow diagram for an exemplary method 10 for forming a memory device. The skilled artisan will recognize that the method 10 can include any or all of the processes illustrated. Additionally, the order of the individual processes can be varied for some portions. The method 10 can start at any of the enumerated processes without deviating from the disclosure. With reference to FIG. 1, at operation 15, a memory stack is formed. At operation 20, a hard mask is etched. At operation 25, an opening, e.g., a memory hole channel, is patterned into the memory stack. At operation 30, transistor layers are deposited. At operation 35, an interlayer dielectric (ILD) is deposited. At operation 40, the memory stack is slit patterned. At operation 45, the sacrificial layer is optionally removed. At operation 50, the first material layers are removed. At operation 55, metal gate materials are deposited. At operation 60, the second material layers are removed. At operation 65, a silicon oxide layer is deposited and an air gap forms.

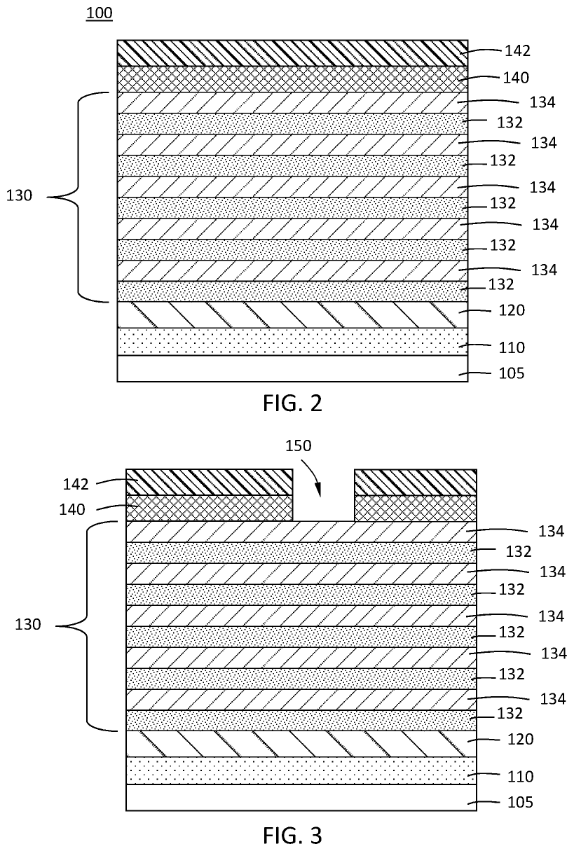

FIGS. 2-14B illustrate a portion of a memory device 100 following the process flow illustrated for the method 10 in FIG. 1.

FIG. 2 illustrates an initial or starting metal stack of an memory device 100 in accordance with one or more embodiments of the disclosure. In some embodiments, the device 100 shown in FIG. 2 is formed on the bare substrate 105 in layers, as illustrated. The device of FIG. 2 is made up of a substrate 105, a semiconductor layer 110, a sacrificial layer 120, a memory stack 130, an oxide layer 140, and a hard mask 142.

The substrate 105 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, silicon nitride, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, nitridize, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

A semiconductor layer 110 is on the substrate 105. In one or more embodiments, the semiconductor layer 110 may also be referred to as the common source line. The semiconductor layer 110 can be formed by any suitable technique known to the skilled artisan and can be made from any suitable material including, but not limited to, poly-silicon (poly-Si). In some embodiments, the semiconductor layer 110 is a common source line that is made of a conductive or a semiconductor material. In some embodiments, the layers below the first material layer 132 and the second material layer 134 stacks can be changed to form source line contacts. Any variation of structure beneath the first and second layer stacks is possible.

An optional sacrificial layer 120 may be formed on the semiconductor layer 110 and can be made of any suitable material. The sacrificial layer 120 in some embodiments is removed and replaced in later processes. In some embodiments, the sacrificial layer 120 is not removed and remains within the memory device 100. In this case, the term “sacrificial” has an expanded meaning to include permanent layers and may be referred to as the conductive layer. In the illustrated embodiment, as described further below, the sacrificial layer 120 is removed in operation 45. In one or more embodiments, the sacrificial layer 120 comprises a material that can be removed selectively versus the neighboring semiconductor layer 110 and first material layer 132.

A memory stack 130 is formed on the sacrificial layer 120. The memory stack 130 in the illustrated embodiment comprises a plurality of alternating first material layers 132 and material layers 134. In one or more embodiments, the first material layers 132 comprise silicon (Si). In one or more embodiments, the second material layers 134 comprises silicon germanium (SiGe). Therefore, in some embodiments, the memory stack 130 comprises alternating layers of silicon (Si) and silicon germanium (SiGe). In other embodiments, the first material layers 132 comprises on or more of silicon (Si) or carbon (C). In one or more embodiments, the second material layers 134 comprise one or more of silicon germanium (SiGe), silicon oxide (SiO), silicon nitride (SiN), silicon carbide (SiC), silicon phosphorus (SiP), silicon oxyphosphorus (SiOP, phosphosilicate glass (PSG)), silicon oxyboride (SiOB, borosilicate glass (BSG)), silicon oxynitride (SiON), silicon oxycarbide (SiOC), silicon boride (SiB), boron carbon (BC), boron nitride (BN), tungsten carbide (WC), and tungsten boron carbide (WBC). In one or more embodiments first material layers 132 and second material layers 134 are deposited by plasma enhanced chemical vapor deposition (PECVD), physical vapor deposition (PVD), or epitaxial deposition. This process can be used for any multiple layer film stack deposition, e.g., Si/SiGe, on any substrate including a dielectric, including, but not limited to, silicon oxide (SiO₂), and a semiconductor substrate, including, but not limited to, silicon (Si) or silicon germanium (SiGe). The advantage of the PECVD process, versus a PVD or epitaxial process, is to achieve better throughput, costs, and tunability of the individual film properties.

While the memory stack 130, illustrated in FIG. 2, has five pairs of alternating first material layers 132 and material layers 134, one of skill in the art recognizes that this is merely for illustrative purposed only. The memory stack 130 may have any number of alternating first material layers 132 and material layers 134. For example, in some embodiments, the memory stack 130 comprises 192 pairs of alternating first material layers 132 and material layers 134. In other embodiments, the memory stack 130 comprises greater than 100 pairs of alternating first material layers 132 and material layers 134, or greater than 200 pairs of alternating first material layers 132 and material layers 134, or greater than 300 pairs of alternating first material layers 132 and material layers 134.

In one or more embodiments, the plasma enhanced chemical vapor deposition (PECVD) process to form the memory stack 130 comprises a surface treatment with plasma. In other words, the sacrificial layer 120 is treated with a plasma prior to deposition of the alternating layers of the first material layers 132 and the second material layers 134. The plasma may comprise ammonia (NH₃) or nitrogen (N₂) and hydrogen (H₂). Without intending to be bound by theory, it is thought that the plasma treatment forms chemical bonds, e.g., Si—N—H chemical bonds on the surface, and, therefore silane (SiH₄) or disilane (Si₂H₆) can better bond with the surface chemical bonds.

After surface treatment with a plasma, a uniform wetting layer is created before deposition. In some embodiments, the wetting layer comprises the same material as the first material layer 132. Thus, in one or more embodiments, the wetting layer comprises silicon (Si). In other embodiments, the wetting layer comprises carbon (C). In one or more embodiments, the silicon wetting layer creates nuclear silicon to aid in film deposition.

After the formation of a silicon wetting layer, a slow linear ramping rate to transition from a low deposition rate to a high deposition rate is performed. Deposition of the first material layer 132 and the second material layer 134 then proceeds under plasma conditions. The PECVD process of some embodiments comprises exposing the substrate surface to a precursor and a co-reactant. In one or more embodiments, the co-reactant can include a mixture of one or more species. In one or more embodiments, the co-reactant gas comprises one or more of argon (Ar), oxygen (O₂), hydrogen (H₂), nitrogen (N₂), hydrogen/nitrogen (H₂/N₂), and ammonia (NH₃).

In one or more embodiments, the individual alternating layers (first material layers 132 and second material layers 134) may be formed to any suitable thickness. In some embodiments, the thickness of each first material layer 132 is approximately equal. In one or more embodiments, each first material layer 132 has a first material layer thickness. In some embodiments, the thickness of each first material layer 132 is approximately equal. As used in this regard, thicknesses which are approximately equal are within +/−5% of each other.

In some embodiments, the thickness of each second material layer 134 is approximately equal. In one or more embodiments, each second material layer 134 has a second material layer thickness. In some embodiments, the thickness of each second material layer 134 is approximately equal. As used in this regard, thicknesses which are approximately equal are within +/−5% of each other. In one or more embodiments, the first material layers 132 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments the second materials layers 134 have a thickness in the range of from about 0.5 to about 40 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm.

Referring to FIG. 3, in one or more embodiments, at operation 20 of method 10, the hard mask 142 is etched to form a gap 150 that exposes a top surface of the second material layer 134 and at least one sidewall. The sidewalls of gap 150 are comprised of the oxide layer 140 and the hard mask 142. Etching the hard mask 142 may be done according to any method known to one of skill in the art.

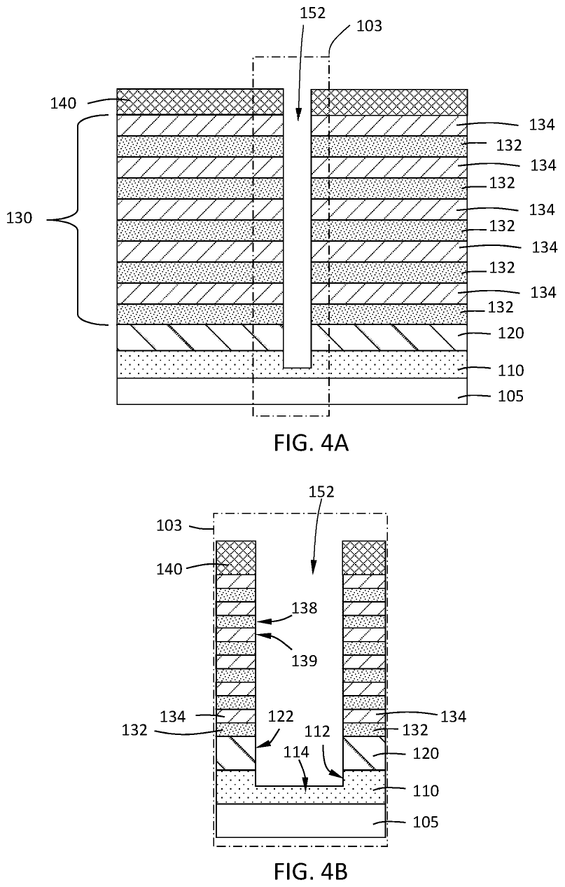

Referring to FIGS. 4A and 4B, at operation 25, in one or more embodiments, an opening 152 is opened through the memory stack 130. In some embodiments, the opening 152 comprises a memory hole channel. In some embodiments, opening the opening 152 comprises etching and removing the hard mask 142, etching through the gap 150, the memory stack 130, sacrificial layer 120, and into semiconductor layer 110. Referring to FIG. 4B, which is an expanded view of region 103, the opening 152 has sidewalls that extend through the memory stack 130 exposing surfaces 138 of the first material layers 132 and surface 139 of the second material layers 134.

In one or more embodiments, the sacrificial layer 120 has surfaces 122 exposed as sidewalls of the opening 152. The opening 152 extends a distance into the semiconductor layer 110 so that sidewall surface 112 and bottom 114 of the opening 152 are formed within the semiconductor layer 110. The bottom 114 of the opening 152 can be formed at any point within the thickness of the semiconductor layer 110. In some embodiments, the opening 152 extends a thickness into the semiconductor layer 110 in the range of about 10% to about 90%, or in the range of about 20% to about 80%, or in the range of about 30% to about 70%, or in the range of about 40% to about 60% of the thickness of the semiconductor layer 110. In some embodiments, the opening 152 extends a distance into the semiconductor layer 110 by greater than or equal to 10%, 20%, 30%, 40%, 50%, 60%, 70% or 80% of the thickness of the semiconductor layer 110.

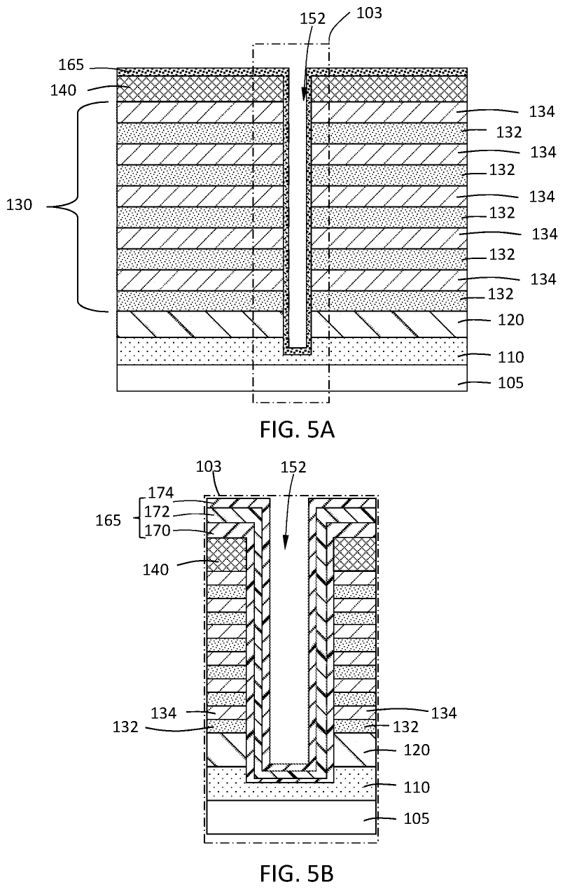

FIGS. 5A and 5B show operation 30 in which transistor layers 165 are conformally deposited into opening 152 adjacent the first material layers 132 and the second material layers 134. The transistor layers 165 can be formed by any suitable technique known to the skilled artisan. In some embodiments, the transistor layers 165 are formed by a conformal deposition process. In some embodiments, the transistor layers 165 are formed by one or more of atomic layer deposition or chemical vapor deposition.

In one or more embodiments, the deposition of the transistor layers 165 is substantially conformal. As used herein, a layer which is “substantially conformal” refers to a layer where the thickness is about the same throughout (e.g., on the top, middle and bottom of sidewalls and on the bottom of the opening 152). A layer which is substantially conformal varies in thickness by less than or equal to about 5%, 2%, 1% or 0.5%.

Referring to FIG. 5B, which is an expanded view of region 103, in one or more embodiments, the transistor layers 165 comprises a blocking oxide layer 170 (or a first oxide layer 170), a nitride trap layer 172 on the first oxide layer 170, a second oxide layer 174 (or the tunneling oxide layer 174) on the nitride trap layer 172 and a poly-silicon layer 170 in the opening 152 on the second oxide layer 174. In one or more embodiments, the blocking oxide layer 170, the charge trap nitride (SiN) layer 174, and the tunneling oxide layer 174 are deposited in the opening 152 on the sidewalls of the opening 152 or on the semiconductor layer 110. In one or more embodiments, before forming a blocking oxide, high-k dielectric materials, such as aluminum oxide or hafnium oxide, may be deposited (i.e. blocking layer is composed of high-k dielectric and silicon oxide).

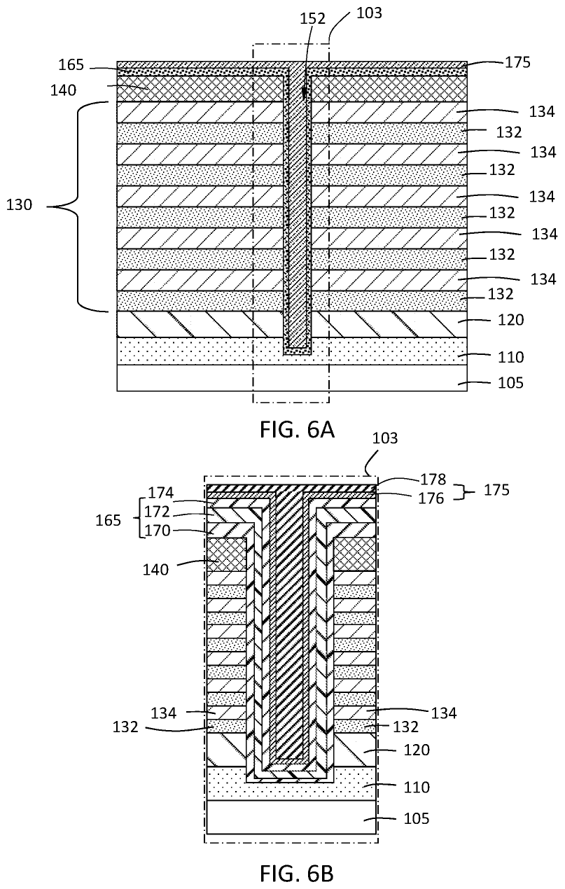

With reference to FIGS. 6A and 6B, in one or more embodiments a poly-silicon (poly-Si) layer 176 is formed in the opening 152 adjacent to the transistor layers 165. The poly-Si layer 176 can be formed directly on the transistor layers 165. The poly-Si layer 176 can be deposited by any suitable technique known to the skilled artisan, including, but not limited to, atomic layer deposition and chemical vapor deposition. In some embodiments, the poly-Si layer 176 is deposited as a conformal layer so that the poly-silicon layer 176 is formed on sidewalls and exposed surface 138, 139, 122, 112 and bottom 114 (see FIG. 4B) of the opening 152.

The poly-silicon layer 176 can have any suitable thickness depending on, for example, the dimensions of the opening 152. In some embodiments, the poly-silicon layer 176 has a thickness in the range of about 0.5 nm to about 50 nm, or in the range of about 0.75 nm to about 35 nm, or in the range of about 1 nm to about 20 nm. In some embodiments, the poly-silicon layer 176 is a continuous film. In one or more embodiments, the poly-silicon layer 176 is formed in a macaroni type with conformal deposition on the tunnel oxide layer 172, the poly-silicon layer 176 having a thickness in a range of about 1 nm to about 20 nm. Then, the opening 152 is filled with a dielectric material 178, such as, but not limited to, silicon oxide (SiO).

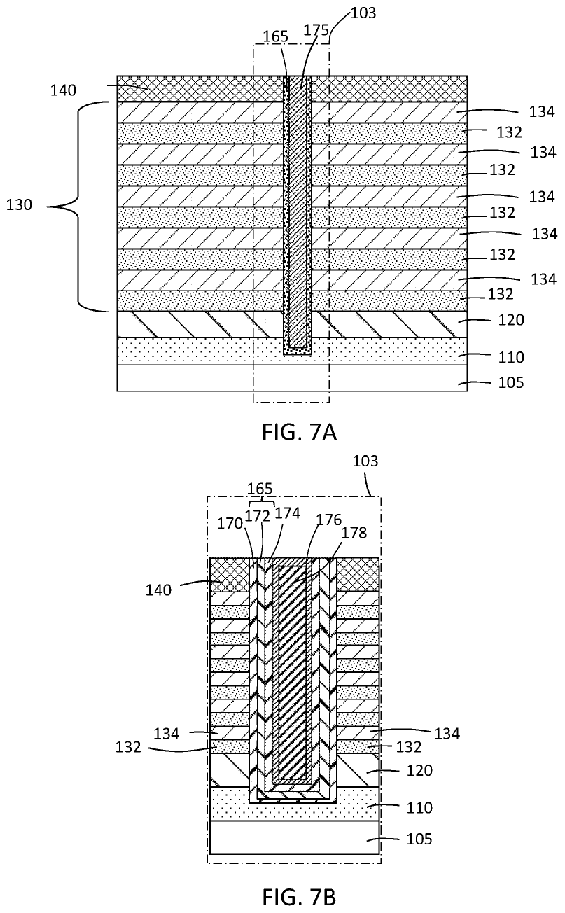

FIGS. 7A and 7B show where the poly-silicon (poly-Si) layer 176 is formed into a plug.

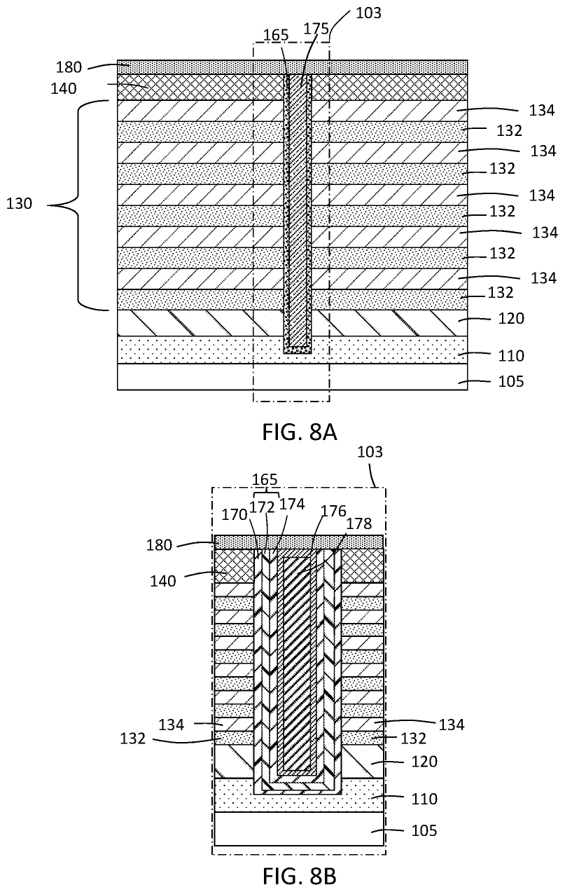

FIGS. 8A and 8B show operation 35 of method 10 where an interlayer dielectric 180 is deposited on a top surface of the oxide layer 140 and the bit line pad 180. The interlayer dielectric (ILD) 180 may be deposited by any suitable technique known to one of skill in the art. The interlayer dielectric 180 may comprise any suitable material known to one of skill in the art. In one or more embodiments, the interlayer dielectric 180 is a low-K dielectric that includes, but is not limited to, materials such as, e.g., silicon dioxide, silicon oxide, carbon doped oxide (“CDO”), e.g., carbon doped silicon dioxide, porous silicon dioxide (SiO₂), silicon nitride (SiN), or any combination thereof. While the term “silicon oxide” may be used to describe the interlayer dielectric 180, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. The same is true for the other materials listed in this disclosure, e.g. silicon nitride, silicon oxynitride, aluminum oxide, zirconium oxide, and the like.

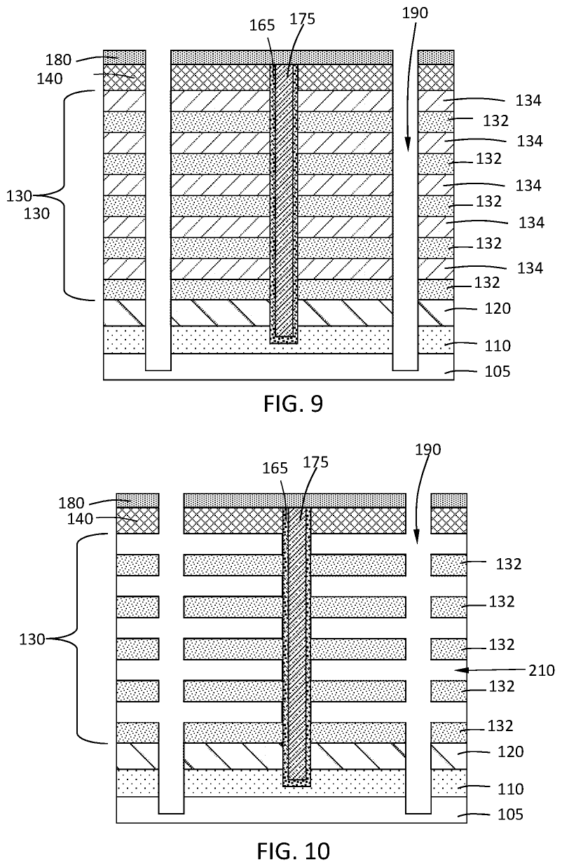

FIG. 9 shows operation 40 of method 10 where the memory stack 130 is slit patterned to form slit pattern openings 190 that extend from a top surface of the interlayer dielectric 180 to the substrate 105.

FIG. 10 shows operation 45 of method 10 where one or more of the second material layers 134, e.g., SiGe layers, are removed to form openings 210 and slit pattern opening 190. In one or more embodiments, the openings 210 have a thickness, t₁, in a range of from about 1 nm to about 50 nm, including about 5 nm, about 7 nm, about 10 nm, about 12 nm, about 15 nm, about 17 nm, about 20 nm, about 22 nm, about 25 nm, about 27 nm, about 30 nm, about 32 nm, about 35 nm, about 37 nm, about 40 nm, about 42 nm, about 45 nm, about 47 nm, and about 50 nm. In one or more embodiments, in removing one or more of the second material layers 134, e.g., SiGe layers, the first side of the second material layers 134, e.g. SiGe layers, are exposed to the slit pattern opening 190, and the first side of the second material layers 134, e.g. SiGe layers, are exposed to an etchant through the slit pattern opening 190.

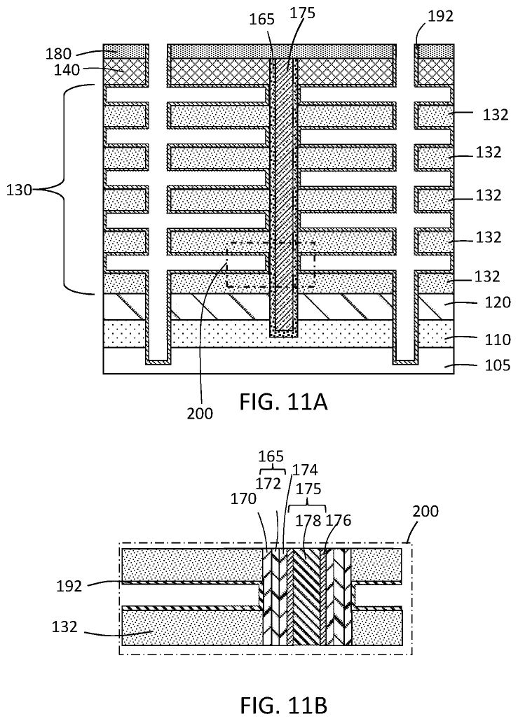

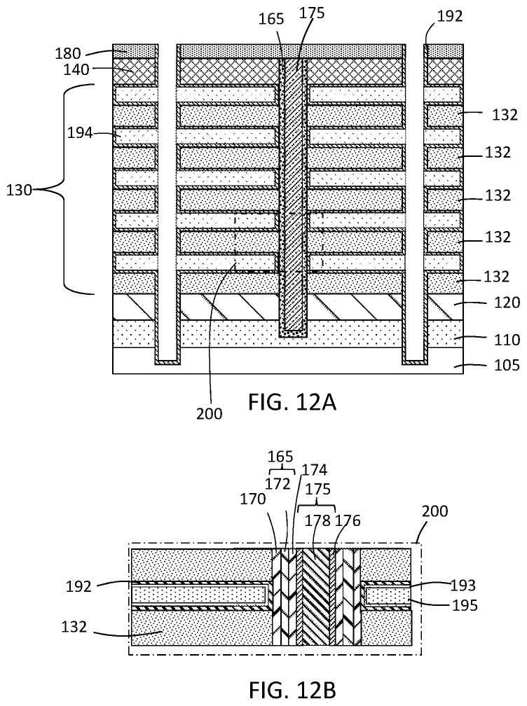

FIGS. 11A-12B show operation 50 of method 10 where a semiconductor material is deposited in slit pattern opening 190 and opening 210. FIGS. 11A and 11B, and FIGS. 12A and 12B show an aluminum oxide layer 192 and a word line replacement material 194 are deposited in the opening 210. FIG. 11B and FIG. 12B are an expanded view of a portion 200 of the device of FIG. 11A and FIG. 12A, respectively. In one or more embodiments, the word line replacement material 194 comprises a nitride liner 193 (e.g., titanium nitride, tantalum nitride, or the like) and a bulk metal 195. In one or more embodiments, the bulk metal 195 comprises one or more of copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh). In one or more embodiments, the bulk metal 195 comprises tungsten (W). In other embodiments, the bulk metal 195 comprises ruthenium (Ru).

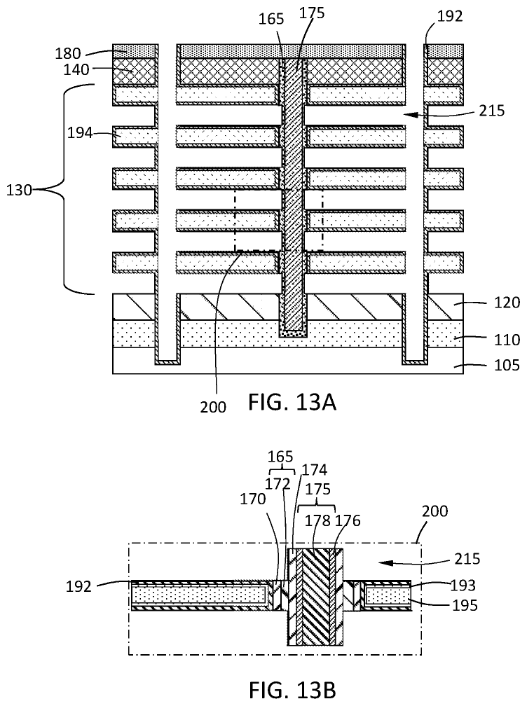

FIGS. 13A and 13B show operation 55 of method 10 where one or more of the first material layers 132, e.g., Si layers, are removed to form openings 215. In one or more embodiments, the openings 215 have a thickness, t₂, in a range of from about 1 nm to about 50 nm, including about 5 nm, about 7 nm, about 10 nm, about 12 nm, about 15 nm, about 17 nm, about 20 nm, about 22 nm, about 25 nm, about 27 nm, about 30 nm, about 32 nm, about 35 nm, about 37 nm, about 40 nm, about 42 nm, about 45 nm, about 47 nm, and about 50 nm. In one or more embodiments, in removing one or more of the first material layers 132, e.g., Si layers, the first side of the first material layers 132, e.g. Si layers, are exposed to the slit pattern opening 190, and the first side of the first material layers 132, e.g. Si layers, are exposed to an etchant through the slit pattern opening 190.

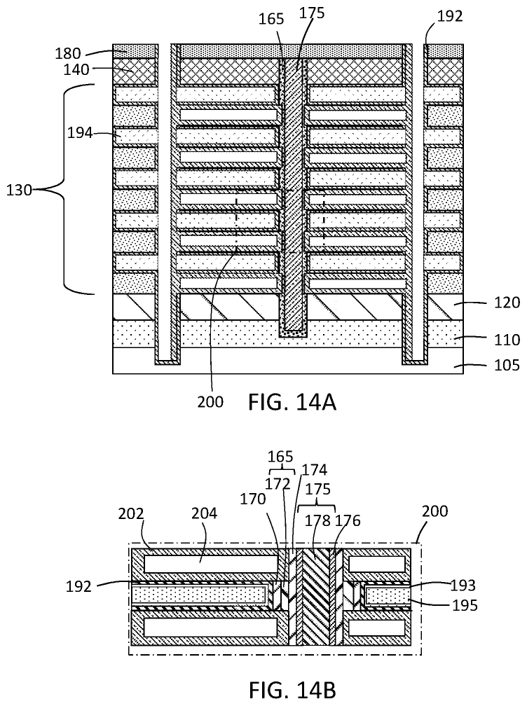

FIGS. 14A and 14B show operation 60 of method 10 where a dielectric material 202 is deposited in openings 215. The dielectric material 202 may comprise any suitable dielectric material known to the skilled artisan. In one or more embodiments, the dielectric material comprises silicon oxide (SiO). In one or more embodiments, when the dielectric material 202 is deposited, an air gap 204 is formed in the opening 215.

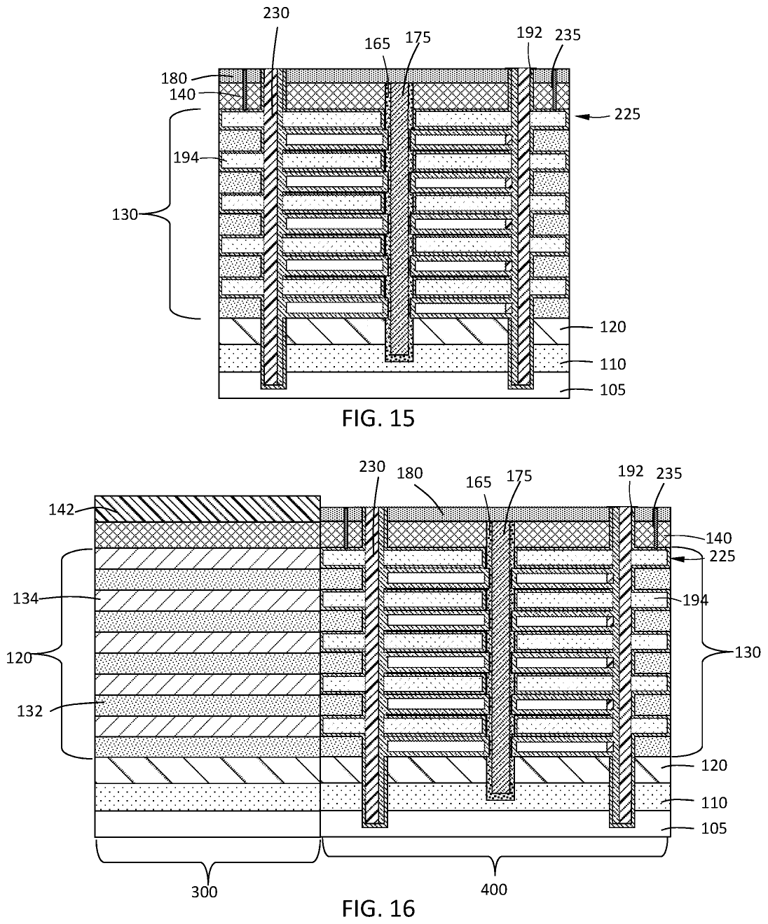

FIG. 15 shows operation 70 of method 10 where word line isolations 235 are formed. The dielectric material 202 forms the isolation for word lines. The slit pattern opening 190 is filled with a fill material 230. The fill material 230 may be any suitable material known to one of skill in the art. In one or more embodiments, the fill material 230 comprises one or more of a dielectric material or a conductor material. As used herein, the term “dielectric material” refers to a layer of material that is an electrical insulator that can be polarized in an electric field. In one or more embodiments, the dielectric material comprises one or more of oxides, carbon doped oxides, silicon oxide (SiO), porous silicon dioxide (SiO₂), silicon oxide (SiO), silicon nitride (SiN), silicon oxide/silicon nitride, carbides, oxycarbides, nitrides, oxynitrides, oxycarbonitrides, polymers, phosphosilicate glass, fluorosilicate (SiOF) glass, or organosilicate glass (SiOCH).

The word line isolations 235 extend through the memory stack 130 a distance sufficient to terminate at one of the word lines 225. In one or more embodiments, the word line isolations 235 can comprise any suitable material known to the skilled artisan. In one or more embodiments, the word line isolation 235 comprises one or more of a metal, a metal silicide, poly-silicon, amorphous silicon, or EPI silicon. In one or more embodiments, the word line contact is doped by either N type dopants or P type dopants in order to reduce contact resistance. In one or more embodiments, the metal of the word line isolation 235 is selected from one or more of copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt).

FIG. 16 shows a semiconductor memory device according to one or more embodiments. The memory device 100 comprises: a memory stack 120 comprising alternating first material layers 132, e.g., silicon (Si) layers, and second material layers 134, e.g. silicon germanium layers, in a first portion 300 of the device 100. A memory stack 130 comprising alternating word line 225 and dielectric layer 202 in a second portion 400 of the device 100.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a device, the method comprising:
treating a surface of a substrate with a plasma, the plasma comprising one or more of ammonia (NH₃), nitrogen (N₂) or hydrogen (H₂);
forming a wetting layer on the substrate;
transitioning from a low deposition rate to a high deposition rate; and
exposing the substrate to at least one precursor to deposit a stack of alternating layers of a first material layer and a second material layer to form a memory stack.

2. The method of claim 1, further comprising:
forming a memory channel through the memory stack;
removing one or more first material layers from the memory stack to form a first opening;
forming a word line replacement material in the first opening;
removing one or more second material layers from the memory stack form a second opening; and
forming a dielectric layer in the second opening.

3. The method of claim 1, wherein the surface of the substrate further comprises one or more of a semiconductor layer and a sacrificial layer.

4. The method of claim 1, wherein the first material layers comprise one or more of silicon (Si) or carbon (C).

5. The method of claim 1, wherein the second material layers comprise one or more of silicon germanium (SiGe), silicon oxide (SiO), silicon nitride (SiN), silicon carbide (SiC), silicon phosphorus (SiP), silicon oxyphosphorus (SiOP, PSG), silicon oxyboride (SiOB, BSG), silicon oxynitride (SiON), silicon oxycarbide (SiOC), silicon boride (SiB), boron carbon (BC), boron nitride (BN), tungsten carbide (WC), and tungsten boron carbide (WBC).

6. The method of claim 1, wherein the first material layers comprise silicon (Si) and the second material layers comprise silicon germanium (SiGe).

7. The method of claim 1, wherein removing the one or more first material layers further comprises:
forming a slit pattern opening through the memory stack, the first side of the first layers exposed be the slit pattern opening; and
exposing the first side of the first layers to an etchant through the slit pattern opening.

8. The method of claim 1, wherein the word line replacement material comprises one or more of tungsten (W), molybdenum (Mo), tantalum (Ta), ruthenium (Ru), niobium (Nb), osmium (Os), zirconium (Zr), iridium (Ir), rhenium (Re), titanium (Ti), and the like.

9. The method of claim 8, wherein the word line replacement material comprises tungsten.

10. The method of claim 8, wherein the word line replacement material further comprises a nitride liner.

11. The method of claim 1, wherein forming the dielectric layer in the second opening comprises depositing a dielectric material into the second opening layer, wherein an air gap is formed in the second opening.

12. A semiconductor memory device comprising:
a memory stack comprising alternating first material layers and second material layers in a first portion of the device;
a memory stack in a second portion of the device, the memory stack comprising
alternating dielectric layers and word lines,
a plurality of bit lines extending through the memory stack; and
word line isolations extending from a top surface of the word lines.

13. The device of claim 12, wherein the word lines comprise one or more of tungsten (W), molybdenum (Mo), tantalum (Ta), ruthenium (Ru), niobium (Nb), osmium (Os), zirconium (Zr), iridium (Ir), rhenium (Re), titanium (Ti).

14. The device of claim 12, wherein the first material layers comprise one or more of silicon (Si) and carbon (C) and the second material layers comprise one or more of silicon germanium (SiGe), silicon oxide (SiO), silicon nitride (SiN), silicon carbide (SiC), silicon phosphorus (SiP), silicon oxyphosphorus (SiOP, PSG), silicon oxyboride (SiOB, BSG), silicon oxynitride (SiON), silicon oxycarbide (SiOC), silicon boride (SiB), boron carbon (BC), boron nitride (BN), tungsten carbide (WC), and tungsten boron carbide (WBC).

15. The device of claim 14, wherein the first material layers comprise silicon (Si) and the second material layers comprise silicon germanium (SiGe).

16. The device of claim 12, wherein the dielectric layers comprise silicon oxide and surround an air gap.

17. The device of claim 12, wherein the word line isolations comprise one or more of copper (Cu), cobalt (Co), tungsten (W), titanium (Ti), molybdenum (Mo), nickel (Ni), ruthenium (Ru), silver (Ag), gold (Au), iridium (Ir), tantalum (Ta), and platinum (Pt).

18. A method of forming memory device, the method comprising:
forming a memory channel through a memory stack, the memory stack comprising alternating layers of a first material layer and a second material layer;
removing one or more first material layers from the memory stack to form a first opening;
forming a word line replacement material in the first opening;
removing one or more second material layers from the memory stack form a second opening;
forming a dielectric layer in the second opening, the dielectric layer having an air gap; and
forming word line isolations

19. The device of claim 18, wherein the first material layers comprise one or more of silicon (Si) and carbon (C).

20. The device of claim 18, wherein the second material layers comprise one or more of silicon germanium (SiGe), silicon oxide (SiO), silicon nitride (SiN), silicon carbide (SiC), silicon phosphorus (SiP), silicon oxyphosphorus (SiOP, PSG), silicon oxyboride (SiOB, BSG), silicon oxynitride (SiON), silicon oxycarbide (SiOC), silicon boride (SiB), boron carbon (BC), boron nitride (BN), tungsten carbide (WC), and tungsten boron carbide (WBC).
